(19) United States
(12) Patent Application Publication
(10) Pub. No.: US 2026/0198389 A1
(43) Pub. Date: Jul. 9, 2026

(54) INTERCONNECT TO ENHANCE RELIABILITY AND PERFORMANCE OF A SEMICONDUCTOR PACKAGE

(71) Applicant: TEXAS INSTRUMENTS INCORPORATED, DALLAS, TX (US)

(72) Inventors: HSUAN-LIEN CHOU, NEW TAIPEI CITY (TW); BOB LEE, ZHONGHE DIST (TW); STANLEY CHOU, BEITOU DIST. (TW)

(21) Appl. No.: 19/015,325

(22) Filed: Jan. 9, 2025

(51) Int. Cl. H01L 23/498; H01L 21/48; H01L 21/56; H01L 23/31; H01L 23/538

(52) U.S. Cl. CPC H10W 90/701; H10W 70/093; H10W 70/611; H10W 70/65; H10W 74/01; H10W 74/111

(57) ABSTRACT

Interconnects and semiconductor packages that include a cavity on lead pads of leads of the interconnect to contain a portion of a solder bump are discussed. One example is a method of forming a semiconductor package. The method includes applying solder to cavities on leads of an interconnect. The cavities are on a top surface of a respective lead. The method also includes mounting a molded interconnect substrate (MIS) on the interconnect. The method additionally includes mounting a semiconductor die electrically coupled to the MIS. The method further includes encapsulating the MIS, the semiconductor die and a portion of the interconnect in a mold compound.

### TECHNICAL FIELD

This description relates to semiconductor packages and interconnects that enhance performance reliability.

### BACKGROUND

Many semiconductor packages include an interconnect that provide inputs and outputs to semiconductor die(s) on the package. In various packages, the semiconductor die(s) are attached to individual leads of the interconnect directly or via a molded interconnect substrate (MIS) that couples to the individual leads of the interconnect. Each lead of the interconnect is coupled to the MIS/semiconductor die via a solder bump or solder paste between a lead pad of the lead and the MIS/semiconductor die.

### SUMMARY

A first example relates to a semiconductor package. The semiconductor package includes an interconnect including leads. Each lead has a top surface with a cavity. The semiconductor package also includes a semiconductor die electrically coupled to the leads. Each cavity in the leads contains a portion of a solder bump.

A second example relates to an interconnect for a semiconductor package. The interconnect includes leads. Each lead has a top surface with a cavity for receiving solder. The interconnect also includes a dam bar mechanically coupled to each of the leads to curtail relative movement of the leads.

A third example relates to a method of forming a semiconductor package. The method includes applying solder to cavities on leads of an interconnect. The cavities are on a top surface of a respective lead. The method also includes mounting a molded interconnect substrate (MIS) on the interconnect. The method additionally includes mounting a semiconductor die electrically coupled to the MIS. The method further includes encapsulating the MIS, the semiconductor die and a portion of the interconnect in a mold compound.

### BRIEF DESCRIPTION OF THE DRAWINGS

FIG. 1A illustrates a portion of an example semiconductor package with leads of an interconnect that have respective cavities on respective top surfaces to contain a portion of respective solder bumps.

FIG. 1B illustrates a close-up view of the dashed region of FIG. 1A, showing a cavity of a lead containing a portion of a solder bump that couples the lead to a molded interconnect substrate (MIS).

FIG. 2A illustrates an example semiconductor package that includes leads with cavities on top surfaces of the leads to contain respective portions of solder bumps for coupling the leads to a MIS that couples the leads to semiconductor dies.

FIG. 2B illustrates the MIS of the example semiconductor package of FIG. 2A that couples semiconductor dies to leads of an interconnect.

FIG. 2C illustrates a perspective view of the example interconnect of the example semiconductor package of FIG. 2A.

FIG. 2D illustrates a close-up side view of a dashed region of FIG. 2C, showing two leads with respective cavities formed in their top surfaces to contain solder bumps.

FIG. 2E illustrates a close-up of side view of a dashed region of FIG. 2D, showing a lead pad of a lead with a cavity containing a portion of a solder bump.

FIG. 3 illustrates a perspective view of an example interconnect and MIS of a semiconductor package.

FIG. 4 illustrates an example interconnect with cavities on the top surfaces of lead pads of the leads of the interconnect.

FIG. 5 illustrates an example interconnect with solder bumps partially contained in cavities on the top surfaces of lead pads of the leads of the interconnect.

FIG. 6 illustrates an example MIS that couples semiconductor dies to an interconnect with cavities on top surfaces of the leads that contain portions of solder bumps.

FIG. 7 illustrates an example interconnect coupled to an example MIS via solder bumps partially contained within cavities formed on the top surfaces of leads of the interconnect.

FIG. 8 illustrates an example interconnect coupled to semiconductor dies via an example MIS coupled to the interconnect by via solder bumps partially contained within cavities formed on the top surfaces of leads of the interconnect.

FIG. 9 illustrates an example semiconductor package that includes leads with cavities on top surfaces of the leads to contain respective portions of solder bumps for coupling the leads to a MIS that couples the leads to semiconductor dies.

FIG. 10 illustrates a table comparing an example interconnect including leads that have cavities on the top surfaces of the leads that contain portions of solder bumps with an interconnect having flat leads.

FIG. 11 illustrates an example method for formation of a semiconductor package that includes an interconnect with leads that have cavities on respective top surfaces to contain portions of respective solder bumps.

### DETAILED DESCRIPTION

This description relates to an interconnect that includes leads that have a cavity on a top surface of a lead pad of the lead(s) and semiconductor packages including such interconnects. The cavity on the top surface is shaped to receive and contain a portion of a solder bump that electrically couples the lead to the semiconductor die, for example, directly, via a molded interconnect substrate (MIS), etc.

In interconnects where leads do not have a cavity in the lead pad, solder paste can creep and/or run down along the sidewall(s) of the lead(s) during reflow and/or after dispensing the solder onto the lead pads. Solder paste that creeps away from a dispensed position on a lead pad or runs down the sidewall of a lead can cause a misconnection between the lead and the MIS. Additionally, at the location of the solder bump, several components co-generate multiple interfaces, and mismatch between the coefficients of thermal expansion (CTEs) of these components results in external shear stress which can peel off the solder bump during temperature cycles.

Various examples include interconnects having leads with cavities for receiving solder on top surfaces of the lead pads of the leads. The cavity contains a portion of the solder bump, curtailing solder creep and solder running down sidewalls of the leads. Contact area between the solder and the lead pad is increased by containing a portion of the solder bump in the cavity. Additionally, examples reduce the stress on a bottom side of the solder bump adjacent to the cavity, curtailing the risk of the solder bump peeling off during temperature cycles.

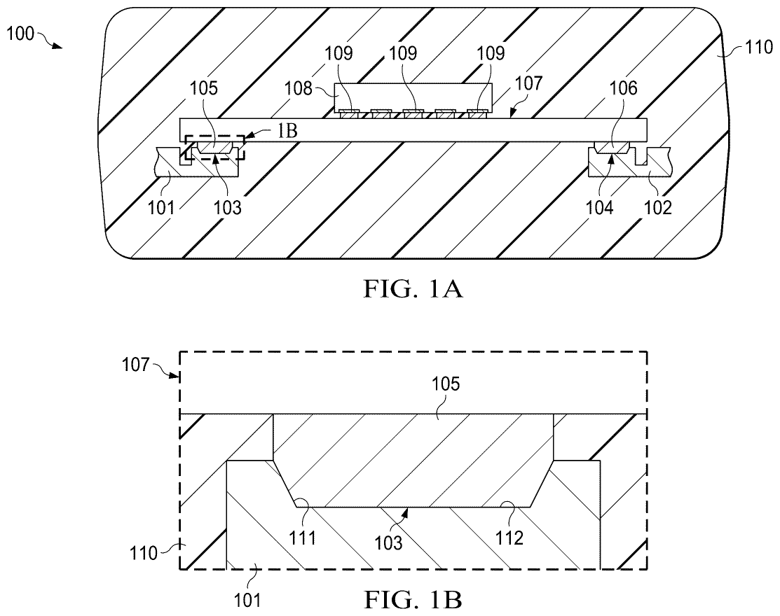

FIG. 1A illustrates a portion of an example semiconductor package 100 (e.g., a small shrink outline package (SSOP)or a different semiconductor package that can be larger or smaller than a SSOP, etc.) with leads 101 and 102 (e.g., having a pitch of 0.7 millimeters or less in one example, although the size of the leads 101 and 102 can be greater or smaller in other examples and/or can vary based on the size and type of the semiconductor package 100, etc.) of an interconnect that have respective cavities 103 and 104 (e.g., having circular profiles, etc.) on respective top surfaces to receive a portion of respective solder bumps 105 and 106. For ease of illustration, solder bumps (e.g., the solder bumps 105 and 106, etc.) are discussed in connection with examples herein. In various examples, however, solder paste is useable instead of solder bumps. The example semiconductor package 100 also includes a molded interconnect substrate (MIS) 107 that is coupled with a semiconductor die 108, for example, via solder attachments to a set of posts such as copper post 109. A mold compound 110 encapsulates the semiconductor die 108, the MIS 107, the solder bumps 105 and 106, and portions of the interconnect (e.g., including portions of the leads 101 and 102 that include the cavities 103 and 104).

In the example semiconductor package 100, the leads 101 and 102 are leads of an interconnect (e.g., which in some examples is a lead frame, etc.). In one example, the leads 101 and 102 are coated with nickel, palladium, and gold, although in various examples the material(s) of the leads 101 and 102 can vary, including based on choices of other materials in the semiconductor package. The cavities 103 and 104 of the leads 101 and 102 receive the respective solder bumps 105 and 106 (or solder paste, etc.) such that solder creep of the solder bumps 105 and 106 is curtailed, and sidewalls of the leads 101 and 102 are free from solder. The cavities 103 and 104 are configured to receive the respective portions of the solder bumps 105 and 106, and to resist distortion of the solder bumps 105 and 106 during temperature cycles (e.g., throughout a range of operating temperatures, during temperature ramp up and ramp down, etc.). Additionally, the cavities 103 and 104 are configured to reduce stress on respective bottom portions of the solder bumps 105 and 106. In the example semiconductor package 100, the cavities 103 and 104 have depths approximately equal to half the height of the solder bumps 105 and 106. In one example, the cavities 103 and 104 have a depth of approximately 30 micrometers and a diameter of approximately 250 micrometers. In various examples, the cavities 103 and 104 are formed via etching. The size and shape of the cavities 103 and 104 (e.g., relative to the lead pad and/or solder bumps 105 and 106, etc.) provide advantages over alternative cavities. For example, a smaller cavity leads to increased likelihood of solder creep away from the cavity, including down the outer sidewalls of the lead. Alternatively, a larger cavity reduces the thickness of the lead sidewalls, increasing the likelihood of a lead breaking.

FIG. 1B illustrates a close-up view of the dashed region of FIG. 1A, showing the cavity 103 of the lead 101 for receiving and containing a portion of the solder bump 105 that couples the lead 101 to the MIS 107. In the example semiconductor package 100, the cavity 103 has a beveled inner surface 111 that extends upward (e.g., to the top surface of the lead 101, to a vertical inner surface that extends to the top surface of the lead 101, etc.) from a flat bottom surface 112 (e.g., which in the example semiconductor package 100 is parallel to the top surface of the lead 101, etc.).

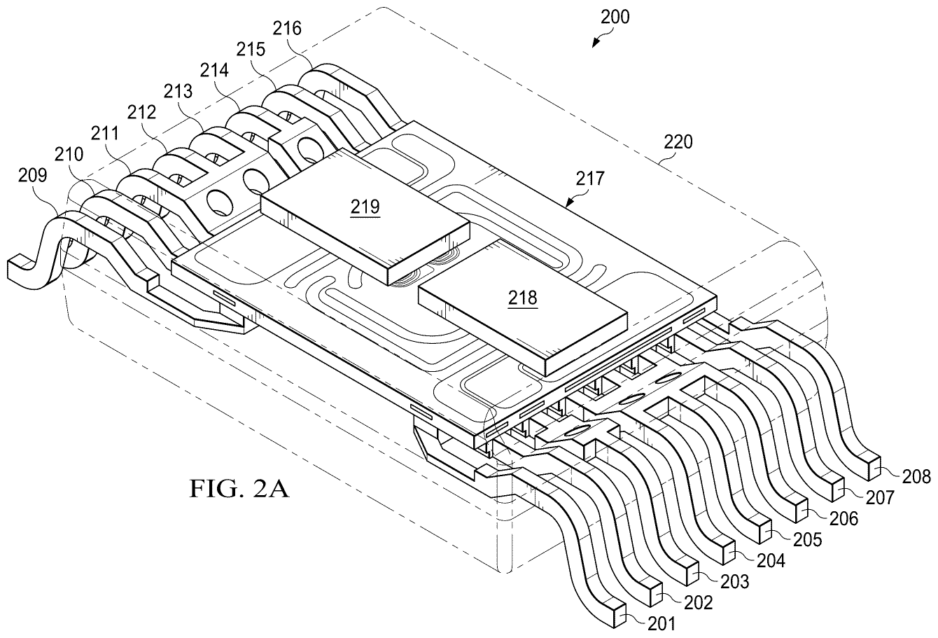

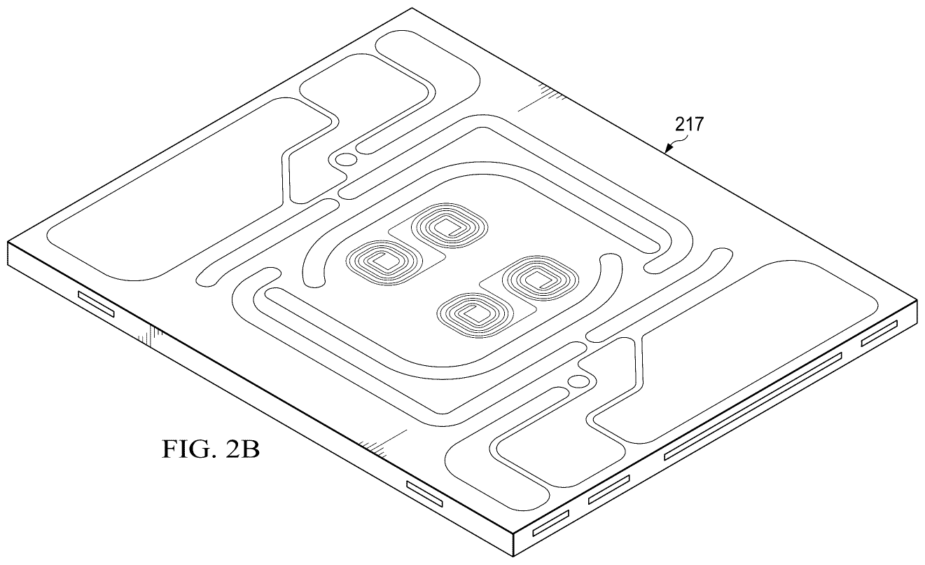

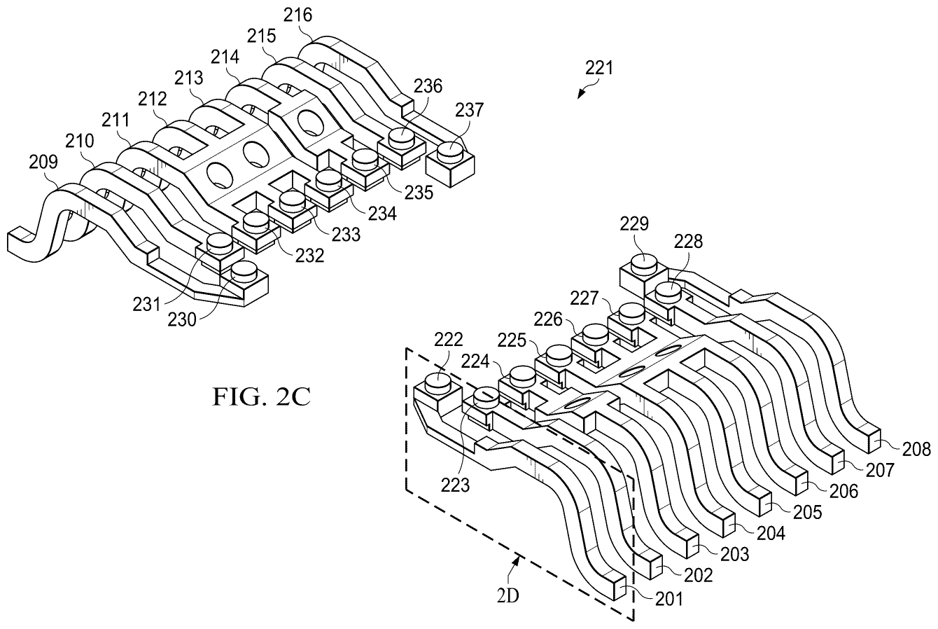

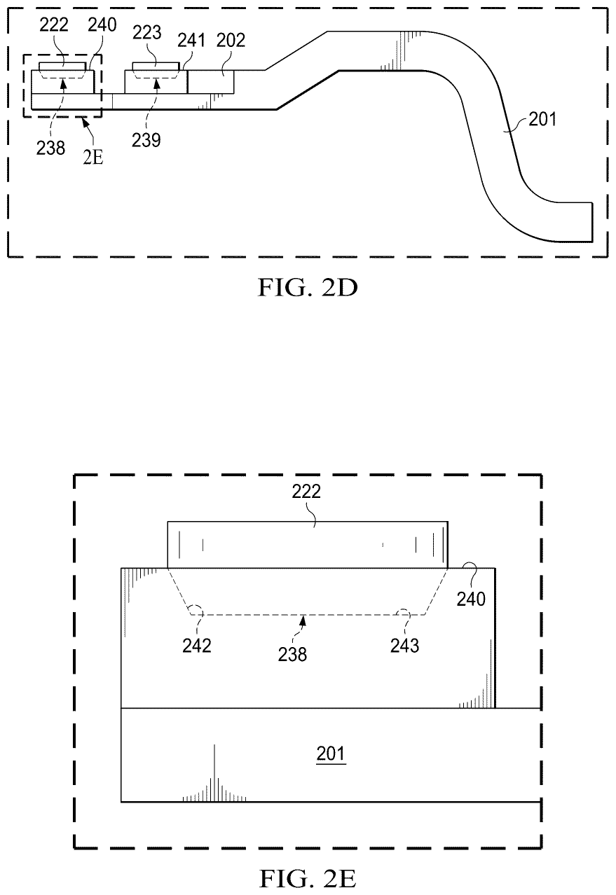

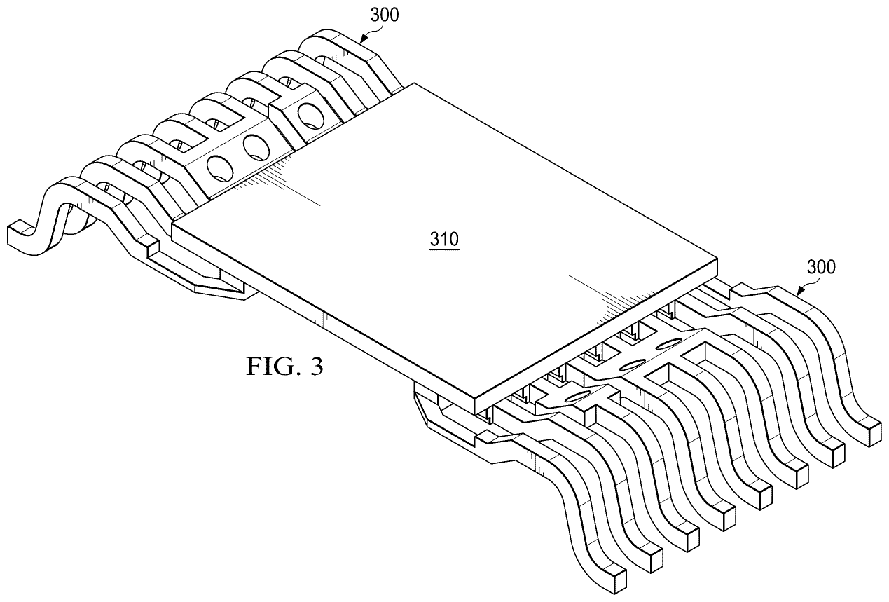

FIG. 2A shows an example semiconductor package 200 (e.g., as one example of a semiconductor package 100, etc.), which is a 16-pin semiconductor package that includes leads 201-216 (e.g., of an interconnect, for example a lead frame, etc.) with cavities on top surfaces of the inner portion of the leads 201-216 to receive and contain respective portions of solder bumps for coupling the leads 201-216 to a MIS 217 that couples the leads 201-216 to semiconductor dies 218 and 219. The MIS 217, the semiconductor dies 218 and 219, and portions of the leads 201-216 are encapsulated in a mold compound 220.

FIG. 2B shows the MIS 217 of the example semiconductor package 200 that couples the semiconductor dies 218 and 219 to the leads 201-216 of the interconnect. The specific design of the MIS (e.g., the MIS 217, etc.) in various examples depends on the number and design of the semiconductor dies (e.g., the semiconductor dies 218 and 219, etc.) and the interconnect (e.g., the interconnect including the leads 201-216, etc.) the MIS is designed to couple together.

FIG. 2C shows a perspective view of the example interconnect 221 of the example semiconductor package 200. The example interconnect 221 includes the leads 201-216, with solder bumps 222-237 partially contained in respective cavities of lead pads of the leads 201-216. FIG. 2D shows a close-up side view of a dashed region of FIG. 2C, showing the leads 201 and 202, which have respective cavities 238 and 239 formed in their top surfaces to contain the solder bumps 222 and 223, respectively. In the example interconnect 221, the lead pads 240 and 241 of the leads 201 and 202 have dimensions of approximately 440 micrometers by 440 micrometers, although various examples can have larger, smaller, and/or differently shaped lead pads. The cavities 238 and 239 are approximately 250 micrometers in diameter at the top surface of the lead and approximately 30 micrometers in depth and contain a portion of the respective solder bumps 222 and 223 equal to approximately half the heights of the solder bumps 222 and 223. The dimensions of the cavities 238 and 239 (e.g., relative to the lead pad and/or solder bumps 222 and 223, etc.) provide advantages over alternative geometries. Smaller cavities increase the likelihood of solder running over the sidewalls of the lead or otherwise creeping away from the cavity. Larger cavities reduce the thickness of the lead around the cavity, increasing the likelihood of the lead breaking. As an additional example, a hemispherical cavity (rather than a cavity with a flat bottom) increases the stress on the underside of the solder bump (or solder paste, etc.), increasing the likelihood of the solder peeling away from the lead pad over temperature cycles.

FIG. 2E shows a close-up of side view of a dashed region of FIG. 2D, showing the lead pad 240 of the lead 201, with the cavity 238 receiving and containing a portion of the solder bump 222. In the example interconnect 221, the cavity 238 has a beveled edge 242 that extends upward from a flat bottom surface 243 to the top side of the lead pad 240 of the lead 201.

The cavity 238 substantially reduces the stress on the bottom side of the solder bump 222 in the example interconnect 221. Mechanical stress modeling of one example showed an approximately 58% reduction in the stress on the bottom side of the solder bump 222 (e.g., with a 63.4 megapascal stress in the example interconnect 221 compared to a 150 megapascal stress for a solder bump deposited on a flat lead pad, etc.). The bottom side of the solder bumps (e.g., the solder bump 222, etc.) is a common failure point. The cavity 238 reduces stress on the bottom side of the solder bump 222, thereby curtailing the risk of failure (e.g., as a result of temperature cycling, etc.).

Referring to FIG. 3, illustrated is a perspective view of an example interconnect 300 coupled to a semiconductor die 310 of a semiconductor package. FIG. 3 shows an example of the interconnect 300 coupled to the semiconductor die 310 directly via a flip chip technique. The leads of the interconnect 300 include cavities on their top surfaces (e.g., facing the semiconductor die 310, etc.) that receive portions of respective solder bumps for coupling the interconnect 300 and the semiconductor die 310. Because portions of the solder bumps are received in the cavities, solder creep and solder flow down sidewalls of the leads is curtailed, increasing the contact area between the solder bumps and the leads of the interconnect 300. Additionally, reduced stress on the bottom sides of the solder bumps curtails external shear stress that can cause the solder bumps to fail during temperature cycles.

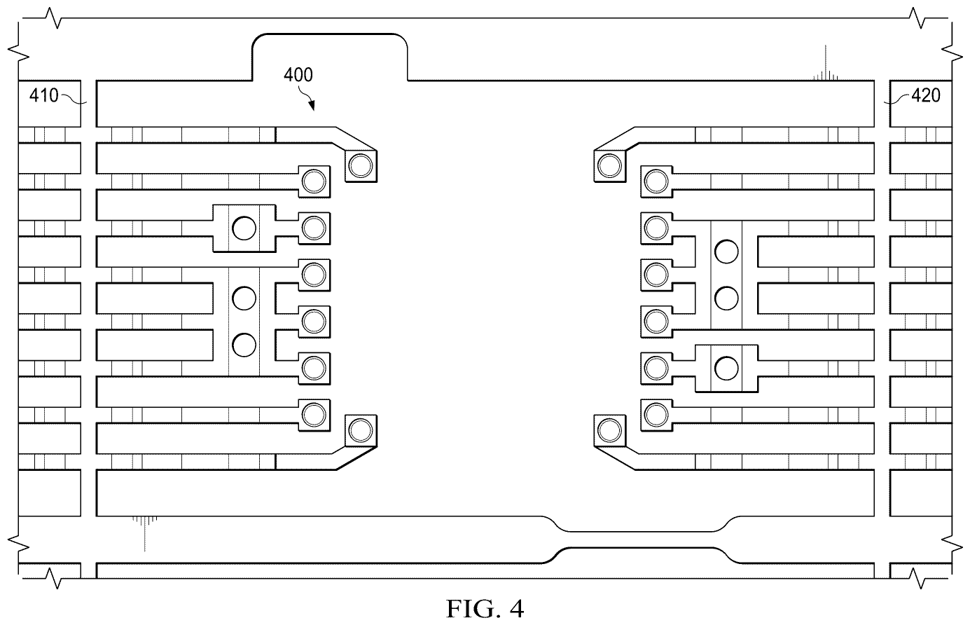

FIGS. 4-9 illustrate stages in formation of a semiconductor package that includes an interconnect with cavities on the top surfaces of lead pads of the leads of the interconnect (e.g., the interconnect 221, the interconnect 300, etc.) to receive solder.

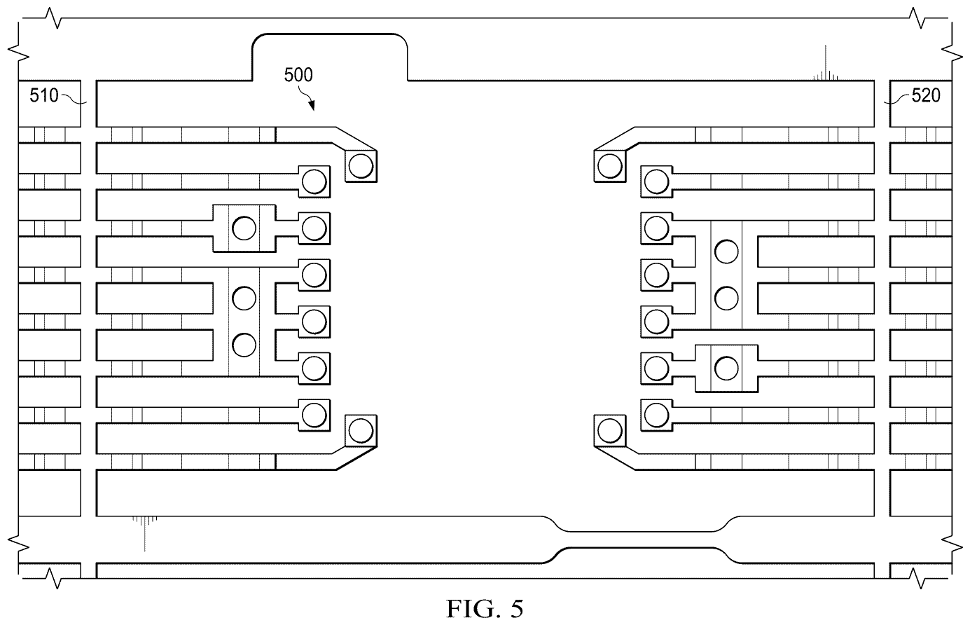

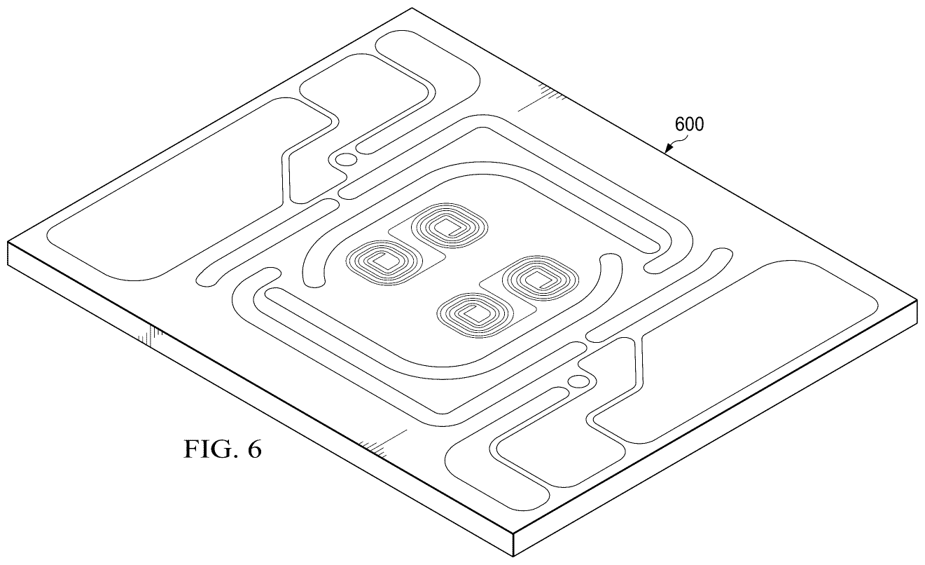

FIG. 4 shows an example interconnect 400 with cavities on the top surfaces of lead pads of the leads of the interconnect 400 to receive solder. The example interconnect 400 (e.g., a leadframe) can include leads of the example interconnect 400 coupled to one of two dam bars 410 and 420 that curtail relative movement of the leads and facilitate alignment of the interconnect 400 to a MIS (e.g., the MIS 107, the MIS 217, etc.) after solder bumps are dispensed on the interconnect 400. FIG. 5 shows an example interconnect 500 with solder bumps partially contained in cavities on the top surfaces of lead pads of the leads of the interconnect 500. The example interconnect 500 includes leads of the example interconnect 500 coupled to one of two dam bars 510 and 520 that curtail relative movement of the leads and facilitate alignment of the interconnect 400 to a MIS (e.g., the MIS 107, the MIS 217, etc.), for example via reflowing and solidizing the solder bumps. FIG. 6 illustrates an example MIS 600 that couples semiconductor dies to an interconnect (e.g., the interconnect 221, the interconnect 300, the interconnect 400, the interconnect 500, etc.) with cavities on top surfaces of the leads that receive portions of solder bumps. In one example, the MIS 600 has a rough copper topside and a backside that includes nickel, palladium, and gold.

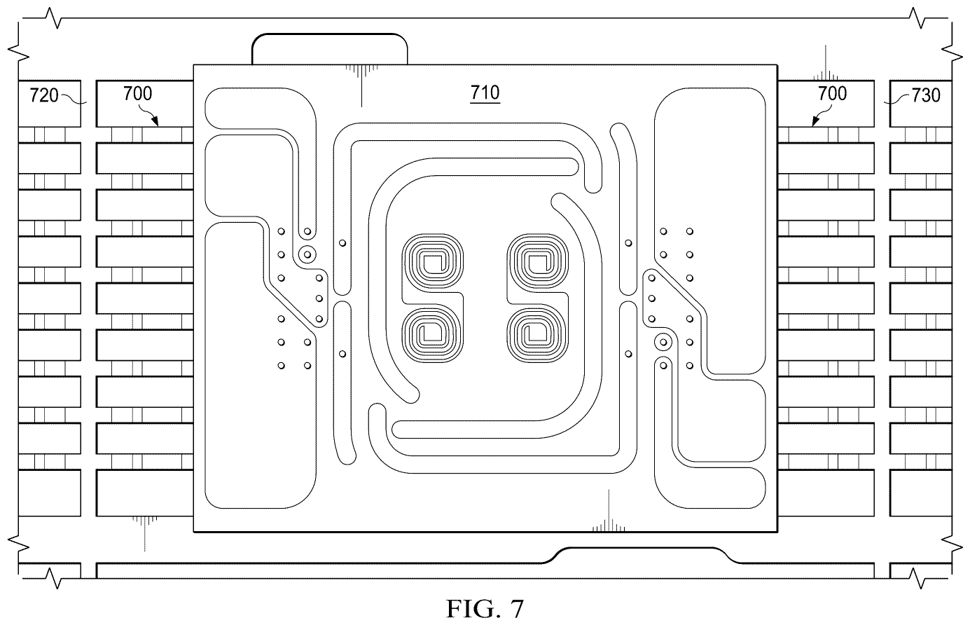

Referring to FIG. 7, illustrated is an example interconnect 700 coupled to an example MIS 710 via solder bumps partially contained within cavities formed on the top surfaces of leads of the interconnect 700 (e.g., by reflowing and solidizing the solder bumps dispensed on the interconnect 700, etc.) to receive portions of the solder bumps. The leads of the interconnect 700 are coupled into two sets by dam bars 720 and 730, which curtail relative movement of the leads and facilitate alignment of the MIS 710 on the interconnect 700 prior to removal of the dam bars 720 and 730.

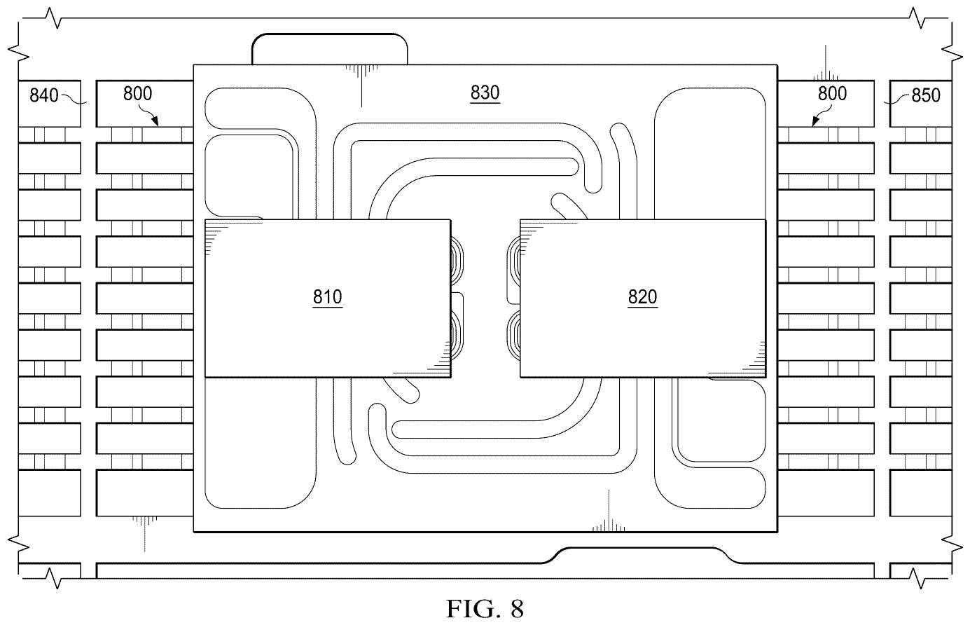

FIG. 8 shows an example interconnect 800 coupled to semiconductor dies 810 and 820 via an example MIS 830 coupled to the interconnect 800 by via solder bumps partially received and contained within cavities formed on the top surfaces of leads of the interconnect 800. The leads of the interconnect 800 are coupled into two sets by dam bars 840 and 850, which curtail relative movement of the leads and facilitate alignment of the MIS 830 on the interconnect 800 prior to removal of the dam bars 840 and 850. In one example, the semiconductor dies 810 and 820 are attached via a flip-chip die technique, such as by flipping the semiconductor dies 810 and 820, dipping solder bumps of the semiconductor dies 810 and 820 in flux, attaching the semiconductor dies 810 and 820 to the MIS 830, reflowing the solder bumps on the semiconductor dies 810 and 820, and solidizing the solder bumps to couple the semiconductor dies 810 and 820 to the MIS 830.

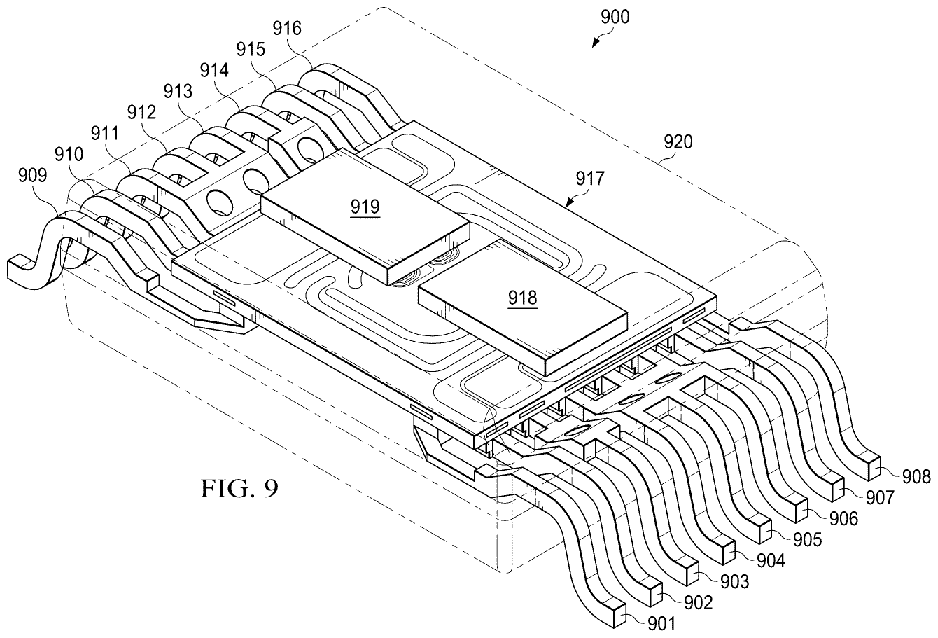

FIG. 9 shows an example semiconductor package 900 (e.g., as an example of the semiconductor package 100, etc.) that includes leads 901-916 (e.g., of an interconnect, for example the interconnect 700, the interconnect 800, etc.) with cavities on top surfaces of the leads 901-916 to receive respective portions of solder bumps for coupling the leads 901-916 to a MIS 917 that couples the leads 901-916 to semiconductor dies 918 and 919. The dam bars shown in FIGS. 7 and 8 have been removed, and the MIS 917, the semiconductor dies 918 and 919, and portions of the leads 901-916 have been encapsulated in a mold compound 920, which is trimmed (e.g., to remove dam bars such as the dam bars 720 and 730 or the dam bars 840 and 850 and separate the leads, etc.) and forming leads to create the semiconductor package 900.

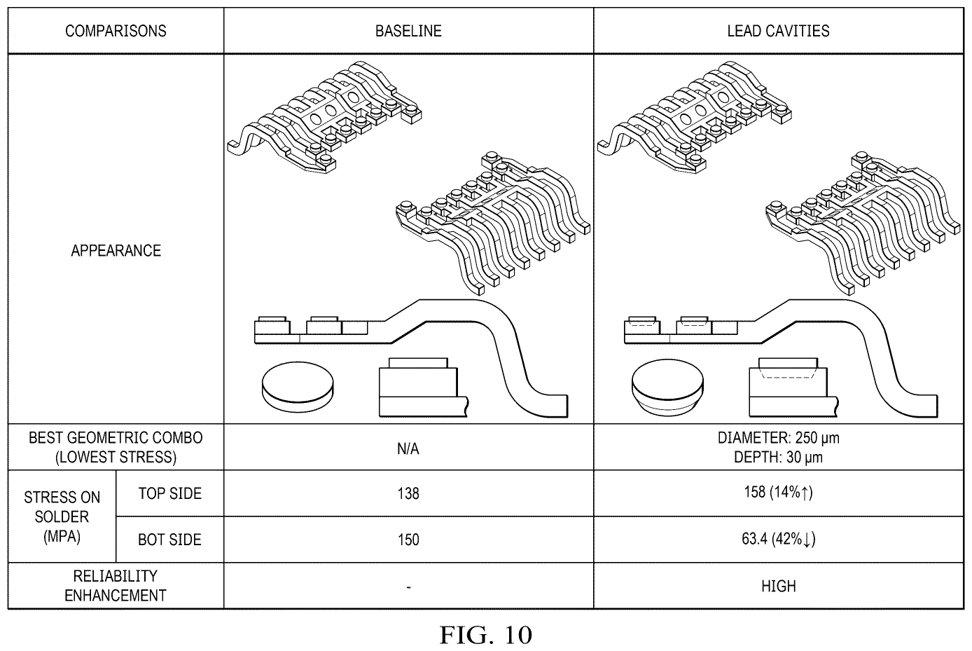

FIG. 10 is a table comparing an example interconnect including leads that have cavities on the top surfaces of the leads that contain portions of solder bumps with an interconnect having flat leads. For the dimensions of the leads of the example interconnect (e.g., with lead pads that are approximately 440 micrometers by approximately 440 micrometers, etc.), a cavity with a diameter of approximately 250 micrometers and a depth of approximately 30 micrometers provided a stress on the bottom side of the solder bump of 63.4 megapascals, which is approximately 42% of the 150 megapascals of stress on the bottom side of a solder bump deposited on the top surface of a lead with a flat top surface. While the leads of the example interconnect had a slightly increased stress (158 megapascals) on the top side of the solder bump compared to the flat lead (138 megapascals), the top side of the solder bump is not a common failure point, unlike the bottom side of the solder bump, which involves several components co-generating multiple interfaces, with mismatch in coefficients of thermal expansion that cause shear stress during temperature cycles.

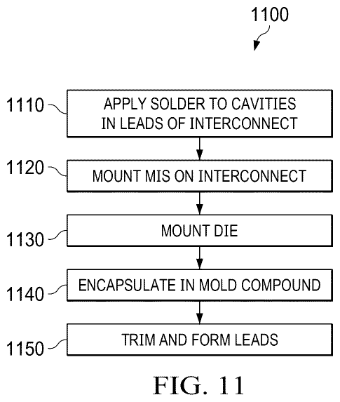

FIG. 11 illustrates a method 1100 for formation of a semiconductor package that includes an interconnect with leads that have cavities on respective top surfaces to receive portions of respective solder bumps, such as the semiconductor package 200 of FIG. 2A or the semiconductor package 900 of FIG. 9.

At 1110, method 1100 includes applying solder to cavities formed (e.g., via etching, stamping, etc.) in the top surfaces of leads of an interconnect (e.g., the cavity 103 in the top surface of the lead 101 of FIG. 1B, the cavities 238 and 239 of the leads 201 and 202 of FIG. 2D, etc.). In some examples, the interconnect is a lead frame, while in other examples the solder is applied to cavities in a different interconnect.

At 1120, method 1100 includes mounting a MIS (e.g., the MIS 107 of FIG. 1A-1B, the MIS 217 of FIGS. 2A-2B, the MIS 600 of FIG. 6, the MIS 710 of FIG. 7, the MIS 830 of FIG. 8, the MIS 917 of FIG. 9, etc.) to the interconnect. In various examples, the MIS is mounted to the interconnect by attaching the MIS to the interconnect and reflowing the solder applied at 1110, which solidizes to couple the MIS to the interconnect.

At 1130, method 1100 includes mounting at least one semiconductor die (e.g., the semiconductor die 108 of FIG. 1A, the semiconductor dies 218 and/or 219 of FIG. 2A, the semiconductor dies 810 and/or 820 of FIG. 8, the semiconductor dies 918 and/or 919 of FIG. 9, etc.) to the MIS. Alternately, in examples without the MIS, the semiconductor die is mounted directly to the interconnect. In various examples, the semiconductor die(s) are attached via a flip-chip die technique, such as by flipping the semiconductor die(s), dipping solder bumps of the semiconductor die(s) in flux, and attaching the semiconductor die(s) to the interconnect, either directly or via attaching the semiconductor die(s) to the MIS, reflowing the solder bumps on the semiconductor die(s), and solidizing the solder bumps to couple the semiconductor die(s) to the MIS.

At 1140, method 1100 includes encapsulating the MIS (in examples including the MIS), the semiconductor die(s), and portions of the interconnect in mold compound (e.g., the mold compound 110 of FIGS. 1A-1B, the mold compound 220 of FIG. 2A, the mold compound 920 of FIG. 9, etc.). In various examples, any of a variety of mold compounds are employed for encapsulating the MIS, semiconductor die(s), and portions of the interconnect. Because containing portions of the solder bumps in cavities on the top surfaces of leads of the interconnect reduces stress on the bottom side of the solder bumps, various examples have a greater tolerance for variations in the coefficient of thermal expansion (CTE) of mold compound than interconnects that apply solder to flat top surfaces of leads.

At 1150, method 1100 includes trimming the interconnect (e.g., removing any dam bars such as the dam bars 410 and 420 of FIG. 4, the dam bars 510 and 520 of FIG. 5, the dam bars 720 and 730 of FIG. 7, the dam bars 840 and 850 of FIG. 8, etc.) to form separate leads and create the semiconductor package (e.g., the semiconductor package 200 of FIG. 2A, the semiconductor package 900 of FIG. 9, etc.).

In this description, unless otherwise stated, “about,” “approximately” or “substantially” preceding a parameter means being within +/−10 percent of that parameter. Modifications are possible in the described embodiments, and other embodiments are possible, within the scope of the claims.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A semiconductor package comprising:
an interconnect comprising leads, each lead having a top surface with a cavity; and
a semiconductor die electrically coupled to the leads;
wherein each cavity in the leads contains a portion of a solder bump.

2. The semiconductor package of claim 1, further comprising:
a molded interconnect substrate (MIS) mounted on the interconnect, wherein the semiconductor die is mounted on the MIS and electrically coupled to the leads through the MIS and through solder bumps of the leads.

3. The semiconductor package of claim 2, further comprising a mold compound encapsulating the semiconductor die, the MIS and a portion of the interconnect.

4. The semiconductor package of claim 1, wherein each cavity comprises a beveled edge extending from a bottom surface of a respective cavity to the top surface of a respective lead.

5. The semiconductor package of claim 4, wherein the bottom surface of each cavity is flat.

6. The semiconductor package of claim 1, wherein a sidewall of the leads is free of solder.

7. The semiconductor package of claim 1, wherein the semiconductor package is a small shrink outline package (SSOP).

8. The semiconductor package of claim 3, wherein the leads have a pitch of 0.7 millimeters or less.

9. The semiconductor package of claim 1, wherein the cavity is configured to resist distortion of the solder bump on each lead during temperature ramp up and down.

10. The semiconductor package of claim 1, wherein the cavity has a depth of about half of a thickness of a corresponding solder bump.

11. The semiconductor package of claim 1, wherein the cavity has a depth of approximately 30 micrometers.

12. The semiconductor package of claim 1, wherein the cavity has a diameter of approximately 250 micrometers.

13. An interconnect for a semiconductor package, the interconnect comprising:
leads, each lead having a top surface with a cavity for receiving solder; and
a dam bar mechanically coupled to each of the leads to curtail relative movement of the leads.

14. The interconnect of claim 13, wherein each cavity comprises a beveled edge extending from a bottom surface of a respective cavity to the top surface of a respective lead.

15. The interconnect of claim 13, wherein the leads have a pitch of 0.7 millimeters or less.

16. The interconnect of claim 13, wherein the cavity has a diameter of approximately 250 micrometers.

17. The interconnect of claim 13, wherein the leads are coated with nickel, palladium and gold.

18. A method of forming a semiconductor package, the method comprising:
applying solder to cavities on leads of an interconnect, wherein the cavities are on a top surface of a respective lead;
mounting a molded interconnect substrate (MIS) on the interconnect;
mounting a semiconductor die electrically coupled to the MIS; and
encapsulating the MIS, the semiconductor die and a portion of the interconnect in a mold compound.

19. The method of claim 18, further comprising trimming and forming the leads of the interconnect.

20. The method of claim 18, wherein sidewalls of the leads are free from solder.
